(19) United States
(12) Patent Application Publication
(10) Pub. No.: US 2025/0329670 A1
(43) Pub. Date: Oct. 23, 2025

(54) ETCHED SPARK GAP INTEGRATED IN SEMICONDUCTOR PACKAGING

(71) Applicant: Atlas Magnetics, Reno, NV (US)

(72) Inventor: John Othniel McDonald, Reno, NV (US)

(21) Appl. No.: 19/256,089

(22) Filed: Jun. 30, 2025

Related U.S. Application Data
(63) Continuation-in-part of application No. 18/581,118, filed on Feb. 19, 2024, now Pat. No. 12,348,008.
(60) Provisional application No. 63/771,923, filed on Mar. 14, 2025.

(51) Int. Cl. H01L 23/60

(52) U.S. Cl. CPC H01L 23/60

(57) ABSTRACT

The present disclosure provides a semiconductor device comprising a first electrode and a second electrode positioned opposite each other with a gap between them, a semiconductor plastic encapsulating the first electrode and the second electrode, a protective plating layer on the first electrode and the second electrode, and a sacrificial layer positioned within the gap. The sacrificial layer is removable to form a spark gap between the first electrode and the second electrode. A method of manufacturing the semiconductor device includes forming the electrodes, depositing a protective plating layer and the sacrificial layer, encapsulating the components with semiconductor plastic, and removing the sacrificial layer to form the spark gap. The protective plating layer may include etch resistant and mechanically hard materials to protect the electrodes during manufacturing and operation.

### CROSS-REFERENCE TO RELATED APPLICATIONS

This application is a continuation-in-part of U.S. application Ser. No. 18/581,118, titled METHOD AND APPARATUS FOR INTEGRATING SPARK GAPS INTO SEMICONDUCTOR PACKAGING, filed Feb. 19, 2024, which is hereby incorporated by reference in its entirety.

### FIELD OF INVENTION

The present disclosure relates to semiconductor devices with integrated electrostatic discharge protection, and more particularly to an etched spark gap structure integrated within semiconductor packaging.

### BACKGROUND

Electrostatic discharge (ESD) protection is a crucial consideration in semiconductor device design and manufacturing. As electronic components continue to shrink in size and increase in complexity, they become more susceptible to damage from electrostatic events. These events can occur during various stages of a device's lifecycle, including manufacturing, handling, and normal operation.

One way ESD can damage circuits is by creating blowouts that leave behind a hole in the circuit. This occurs when the voltage discharged during the ESD event exceeds the voltage breakdown threshold of the material to a high enough degree that the circuit material explodes. Semiconductor devices need protection against two main sources of ESD. The first source is humans, who may touch the semiconductor and cause an ESD event. To protect against this source of ESD, semiconductor protection is designed to withstand a charge under the JEDEC 22-A114-B standard, which models an ESD event from a human source, otherwise known as the human body model (HBM). Another source of ESD comes from metal-to-metal contact that may occur during manufacturing, commonly modeled in the industry as a charged device model (CDM). Semiconductor Integrated Circuits (ICs) are designed to protect against both HBM and CDM. Various industry-standard protection levels depend on the application's environmental requirements.

Several methods exist to protect semiconductor ICs from electrostatic discharge events. Two commonly implemented approaches are: 1) utilizing a diode connected from a pin to the IC's ground or power, which shunts the ESD current away from the IC die along an electrical path designed to withstand the ESD event; and 2) employing a MOSFET switch that activates during an ESD event, connecting the pin to the IC's ground or power to redirect the ESD current away from the IC die through an appropriately rated electrical path. These ESD protection circuits consume valuable IC die area and can contribute to the overall cost of the IC.

Spark gap devices represent an alternative protection mechanism that functions by positioning a portion of the circuit to be protected in close proximity to a ground point at a location where minimal permanent damage would occur during an ESD event. While spark gaps are utilized in various applications, they are rarely implemented on the surface of ICs because the generated spark would typically create a destructive hole in the nearby circuit, and the necessary isolation region would be prohibitively expensive to implement.

Traditional spark gap designs often involve discrete components or specialized structures that are separate from the main semiconductor package. This approach can lead to increased manufacturing complexity, larger overall device footprints, and potential reliability issues due to the connections between the protection components and the protected circuitry.

The semiconductor industry continually seeks innovative approaches to enhance ESD protection while maintaining or improving other device characteristics such as performance, reliability, and cost-effectiveness. As devices become more complex and operate at higher speeds and lower voltages, the demands on ESD protection systems increase. Balancing these requirements with the need for miniaturization, integration, and lower costs is an ongoing focus of research and development in the field.

Advancements in semiconductor manufacturing techniques, including precise etching processes and novel materials, open up new possibilities for creating integrated ESD protection structures. These developments may enable the creation of more effective and efficient spark gap designs that can be incorporated into existing semiconductor packaging processes.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a etched spark gap semiconductor device is provided. The device includes a first electrode and a second electrode positioned opposite each other with a gap between them. A semiconductor plastic encapsulating the first electrode and the second electrode. A protective plating layer is provided on the first electrode and the second electrode. A sacrificial layer is positioned within the gap, wherein the sacrificial layer is removable to form a spark gap between the first electrode and the second electrode.

According to other aspects of the present disclosure, the semiconductor device may include one or more of the following features. The first electrode may be electrically coupled to an input/output connection and the second electrode may be electrically coupled to a ground connection. The protective plating layer may comprise at least one etch resistant material. The etch resistant material may be a gold metal. The protective plating layer may comprise at least one material with a greater mechanical hardness than copper. At least one of the materials with a greater mechanical hardness than copper may be a nickel metal. The sacrificial layer may comprise a copper metal. The sacrificial layer may be removed.

According to another aspect of the present disclosure, a method of manufacturing a semiconductor device with an integrated spark gap is provided. The method includes forming a first electrode and a second electrode on a substrate. The method also includes depositing a sacrificial layer between the first electrode and the second electrode. Additionally, the method includes depositing a protective plating layer on the first electrode and the second electrode. The method further includes encapsulating the first electrode, the second electrode, and the sacrificial layer with a semiconductor plastic. Finally, the method includes removing the sacrificial layer to form a spark gap between the first electrode and the second electrode.

According to other aspects of the present disclosure, the method may include one or more of the following features. The protective plating layer may comprise at least one etch resistant material. The etch resistant material may be a gold metal. Removing the sacrificial layer may comprise etching the sacrificial layer with an acid. The method may further comprise forming an input/output connection electrically coupled to the first electrode and forming a ground connection electrically coupled to the second electrode. The method may also include sawing the semiconductor plastic to expose the sacrificial layer prior to removing the sacrificial layer. Depositing the protective plating layer may comprise depositing a nickel layer on the first electrode and the second electrode, depositing a palladium layer on the nickel layer, and depositing a gold layer on the palladium layer.

According to yet another aspect of the present disclosure, a method of manufacturing a semiconductor device with an embedded spark gap is provided. The method includes forming a first electrode and a second electrode on a substrate. The method also includes depositing a protective plating layer on the first electrode and the second electrode prior to depositing the sacrificial layer. Additionally, the method includes depositing a sacrificial layer between the first electrode and the second electrode and forming copper pillars on the sacrificial layer. The method further includes encapsulating the first electrode, the second electrode, the sacrificial layer, and the copper pillars with a semiconductor plastic. The method also includes exposing the copper pillars and etching out the sacrificial layer through the exposed copper pillars to form a spark gap between the first electrode and the second electrode.

According to other aspects of the present disclosure, the method of manufacturing a semiconductor device with an embedded spark gap may include one or more of the following features. The protective plating layer may comprise at least one etch resistant material. The etch resistant material may be a gold metal. Depositing the protective plating layer may comprise depositing a nickel layer on the first electrode and the second electrode, depositing a palladium layer on the nickel layer, and depositing a gold layer on the palladium layer. The method may further comprise sealing at least one void, left by the etching out of the copper pillars, with an additional layer of semiconductor plastic.

The disclosed techniques allow for the creation of spark gap protection for individual input/output connections on a semiconductor chip. In some implementations, a separate spark gap structure may be formed for each input/output of the chip. This approach may provide tailored protection for each connection point while minimizing overall device size. By integrating the spark gap directly into the semiconductor packaging, the disclosed methods may enable more compact and cost-effective electrostatic discharge protection compared to traditional approaches using separate discrete components. The embedded nature of the spark gap may also allow for more precise control over the spark gap dimensions and characteristics.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates an orthogonal view of a spark gap structure, according to aspects of the present disclosure.

FIG. 2 illustrates a circuit diagram of a spark gap device, according to an embodiment.

FIG. 3 illustrates a top-down orthogonal view of a spark gap structure, according to aspects of the present disclosure.

FIG. 4 illustrates a top-down cross-sectional view of a spark gap structure, according to an embodiment.

FIG. 5 illustrates an orthogonal view of a spark gap structure with a dry film pattern, according to aspects of the present disclosure.

FIG. 6 illustrates a top-down view of a spark gap structure with a sacrificial layer, according to an embodiment.

FIG. 7 shows an orthogonal view of a spark gap structure with a sacrificial layer, according to aspects of the present disclosure.

FIG. 8 shows an orthogonal view of a spark gap structure encapsulated in semiconductor plastic, according to an embodiment.

FIG. 9 illustrates a cross-sectional orthogonal view of a semiconductor device structure with a sawing line, according to aspects of the present disclosure.

FIG. 10 illustrates a cross-sectional orthogonal view of a semiconductor device structure with an exposed sacrificial layer, according to an embodiment.

FIG. 11 illustrates a cross-sectional view of a spark gap structure embedded within semiconductor plastic, according to aspects of the present disclosure.

FIG. 12 illustrates a top-down view of a circular spark gap arrangement, according to an embodiment.

FIG. 13a illustrates an isometric view of a spark gap structure, according to aspects of the present disclosure.

FIG. 13b illustrates a cross-sectional orthogonal view of a spark gap structure, according to an embodiment.

FIG. 14a illustrates a top-down view of a spark gap structure with copper pillars, according to aspects of the present disclosure.

FIG. 14b illustrates a cross-sectional view of a spark gap structure with copper pillars, according to an embodiment.

FIG. 15a illustrates an orthogonal view of a spark gap structure with etchant holes, according to aspects of the present disclosure.

FIG. 15b illustrates a cross-sectional orthogonal view of a spark gap structure with etchant holes, according to an embodiment.

FIG. 16a illustrates an orthogonal view of a sealed spark gap structure, according to aspects of the present disclosure.

FIG. 16b illustrates a cross-sectional view of a spark gap structure with etchant holes, according to an embodiment.

FIG. 17 illustrates an orthogonal view of a layered spark gap structure, according to aspects of the present disclosure.

FIG. 18 illustrates a top-down orthogonal view of multiple arraigned spark gaps, according to an embodiment.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

The present disclosure relates to semiconductor devices with integrated spark gap protection. In particular, the disclosure describes methods and structures for embedding spark gaps within semiconductor packaging materials. This approach may provide advantages in terms of size, cost, and precision compared to traditional discrete spark gap components.

In some cases, multiple spark gaps may be arranged within a single semiconductor device to provide protection for multiple connection points. This configuration may be particularly useful for multi-pin chips, allowing for comprehensive electrostatic discharge protection across numerous inputs and outputs.

The spark gap structures described herein may be partially embedded or fully embedded within the semiconductor packaging material. Partial embedding may allow for some exposure of the spark gap components, while full embedding may provide complete encapsulation within the packaging material. The choice between partial and full embedding may depend on factors such as desired protection level, manufacturing considerations, and specific application requirements or intended use. For example, the partially embedded spark gaps may be well suited to provide ESD protection on multi-pin chips.

By integrating the spark gap directly into the semiconductor packaging, the disclosed methods may enable more compact and cost-effective electrostatic discharge protection compared to traditional approaches using separate discrete components. The etched nature of the spark gap also allows for more precise control over the spark gap dimensions and characteristics even while embedded in the chip packaging.

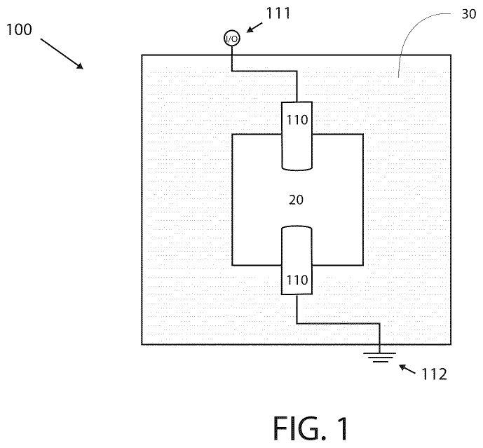

FIG. 1 illustrates an orthogonal view of a spark gap structure 100. The spark gap structure 100 may include a first electrode 110 and a second electrode 110 positioned opposite each other with an electrode gap 20 between them. In some cases, the first electrode 110 and the second electrode 110 may be encapsulated within a semiconductor plastic 30. The semiconductor plastic 30 may be a glass-filled epoxy plastic capable of supporting high-resolution electroplated metal.

In some implementations, the electrode gap 20 may be precisely controlled. For example, the electrode gap 20 may be controlled down to about 5 μm, with an exemplary embodiment having an electrode gap 20 of around 12 μm. This precise control of the electrode gap 20 may allow for tailored spark gap characteristics.

The spark gap structure 100 may include an input/output (I/O) connection 111 electrically coupled to the first electrode 110. In some cases, a ground connection 112 may be electrically coupled to the second electrode 110. The I/O connection 111 and the ground connection 112 may extend through the semiconductor plastic 30, providing electrical connectivity to external circuitry.

The semiconductor plastic 30 may provide structural support and electrical isolation for the electrodes 110. By encapsulating the electrodes 110 within the semiconductor plastic 30, the spark gap structure 100 may be integrated directly into semiconductor packaging, potentially offering advantages in terms of size, cost, and precision compared to traditional discrete spark gap components.

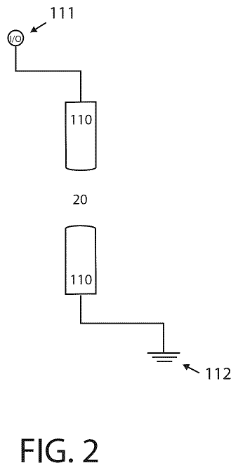

FIG. 2 illustrates a circuit diagram showing the arrangement of electrodes in the spark gap structure 100. The spark gap structure 100 may include a first electrode 110 and a second electrode 110 positioned opposite each other with the electrode gap 20 between them. Each electrode 110 may comprise an outer electrode portion 120 and an inner electrode portion 121.

In some cases, the outer electrode portion 120 and the inner electrode portion 121 may be delineated by a protective plating layer. The protective plating layer, in some cases, may extend about a micron or two past the electrode 110. This extension of the protective plating layer may contribute to the increased size of the inner electrode portion 121 compared to the outer electrode portion 120.

The electrode 110 may be made of various conductive materials. In some implementations, the electrode 110 may comprise copper or nickel. The use of copper or nickel as an electrode material provides certain electrical and mechanical properties suitable for spark gap applications including providing a low impedance path for electrostatic events to follow.

A protective plating layer may be deposited on the first electrode 110 and the second electrode 110. This protective plating layer may serve multiple purposes, such as, preventing the electrodes from being etched out when a sacrificial layer is etched out, and enhancing the durability of the electrodes 110, improving their resistance to wear during spark gap events.

The spark gap structure 100 may include an input/output (I/O) connection 111 electrically coupled to the first electrode 110. In some cases, a ground connection 112 may be electrically coupled to the second electrode 110. The I/O connection 111 and the ground connection 112 may extend away from their respective electrodes 110, providing electrical connectivity to external circuitry.

The inner electrode portion 121 may extend slightly beyond the outer electrode portion 120 toward the electrode gap 20. This configuration may create a defined spacing between the opposing electrodes 110. The outer electrode portion 120 may provide the main conductive path, while the inner electrode portion 121 may form the spark gap interface.

The electrode gap 20 between the inner electrode portions 121 may define the distance across which electrical discharge can occur when the spark gap structure 100 is in operation. The precise control of this electrode gap 20 may allow for tailored spark gap characteristics within the semiconductor plastic 30.

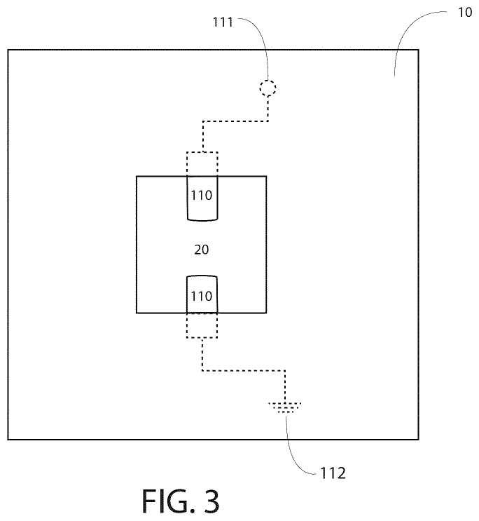

The manufacturing process for the spark gap structure 100 may begin with the application of a dry film 10 and the formation of electrodes 110. FIG. 3 illustrates a top-down orthogonal view of an initial stage in this process.

In some cases, a dry film 10 may be applied to a substrate. The dry film 10 may serve as a pattern for a sacrificial layer that will be formed in subsequent steps. The dry film 10 may be positioned to cover specific areas of the substrate while leaving other areas exposed.

FIG. 3 shows two electrodes 110 positioned on opposite sides of an electrode gap 20. One electrode 110 may be connected to an I/O 111 connection, while the opposing electrode 110 may be connected to a ground 112 connection. The dry film 10 may cover the majority of the structure while leaving exposed areas around the electrode gap 20.

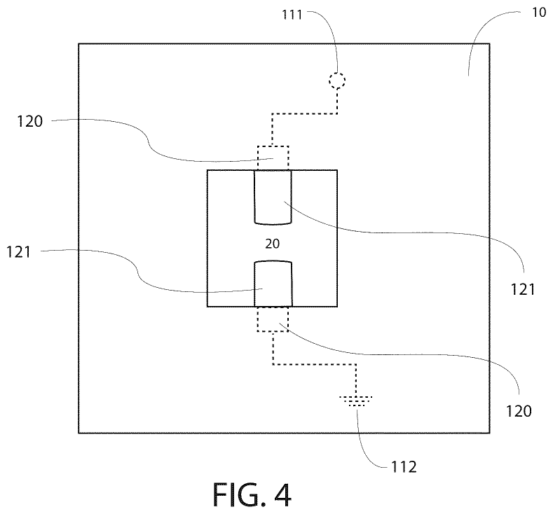

FIG. 4 provides a top-down cross-sectional view of the spark gap structure 100 at the next stage of the manufacturing process. In this figure, the electrodes 110 are shown to comprise outer electrode portions 120 and inner electrode portions 121. The inner electrode portions 121 may extend from the outer electrode portions 120 toward the electrode gap 20.

In some cases, the semiconductor plastic 30 used in the manufacturing process may be Ajinomoto Build-up Film (ABF). ABF may provide certain properties that make the semiconductor plastic 30 suitable for supporting high-resolution electroplated metal structures.

The process of forming the first electrode 110 and the second electrode 110 on a substrate may involve various techniques. In some cases, the electrodes 110 may be formed through deposition, for example, an electroplating processes. The specific method used may depend on factors such as the desired electrode material and the required precision of the electrode dimensions.

The dry film 10 shown in FIG. 4 may define the boundaries of the electrode portions. The inner electrode portions 121 may be positioned closer to the electrode gap 20 than the outer electrode portions 120. In some cases, the inner electrode portions 121 may have been plated with a protective layer, causing them to increase in size compared to the outer electrode portions 120.

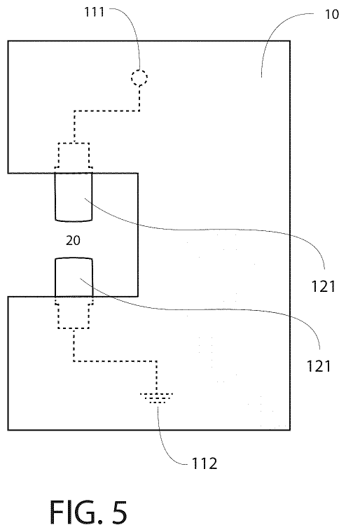

FIG. 5 illustrates an orthogonal view of the spark gap structure 100 showing electrodes 110 with a dry film 10 pattern. The dry film 10 may be positioned over portions of the electrodes 110, leaving exposed areas of the inner electrode portion 121. The dry film 10 pattern may define regions where subsequent processing steps will occur, particularly around the inner electrode portion 121 adjacent to the electrode gap 20.

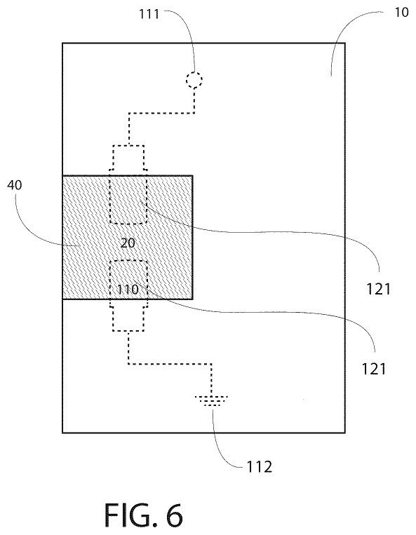

In some cases, a sacrificial layer may be deposited between the first electrode 110 and the second electrode 110. FIG. 6 illustrates a top-down view of the spark gap structure 100 showing a sacrificial layer 40 configuration. The sacrificial layer 40 may be formed between the electrodes 110, occupying the space between the inner electrode portions 121. The sacrificial layer 40 may define the region that will later form the spark gap after removal of the sacrificial layer 40.

The sacrificial layer 40 may comprise various materials. In some cases, the sacrificial layer 40 may comprise a copper metal. The use of copper as the sacrificial layer 40 material may allow for precise control over the dimensions of the eventual spark gap.

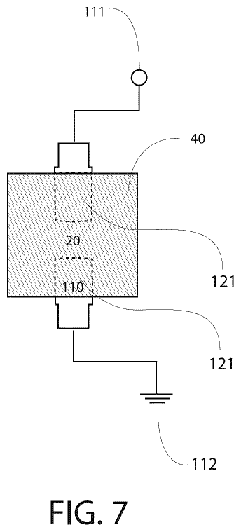

FIG. 7 shows an orthogonal view of the spark gap structure 100 after the formation of the sacrificial layer 40. The sacrificial layer 40 may be positioned between the inner electrode portions 121 of the opposing electrodes 110, defining the gap that will eventually form the spark gap after the sacrificial layer 40 is removed.

In some cases, the sacrificial layer 40 may be shaped to define specific dimensions and geometry of the final spark gap structure 100. For example, the sacrificial layer 40 may have a rounded end in some implementations. This shaping of the sacrificial layer 40 may allow for customization of the spark gap characteristics.

The sacrificial layer 40 may be removable to form a spark gap between the first electrode 110 and the second electrode 110. The removal process may occur in subsequent manufacturing steps, allowing for the creation of a precisely defined spark gap within the semiconductor plastic 30.

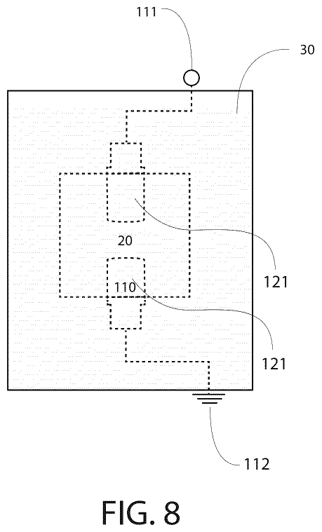

The manufacturing process for the spark gap structure 100 may continue with the encapsulation of the components within semiconductor plastic 30. FIG. 8 illustrates an orthogonal view of the spark gap structure 100 after encapsulation. The semiconductor plastic 30 may encapsulate the electrodes 110, including the inner electrode portions 121 and outer electrode portions 120, as well as the sacrificial layer 40.

In some cases, the semiconductor plastic 30 may provide structural support and electrical isolation for the spark gap components. The encapsulation process may involve applying the semiconductor plastic 30 over the entire structure, including the electrodes 110 and the sacrificial layer 40.

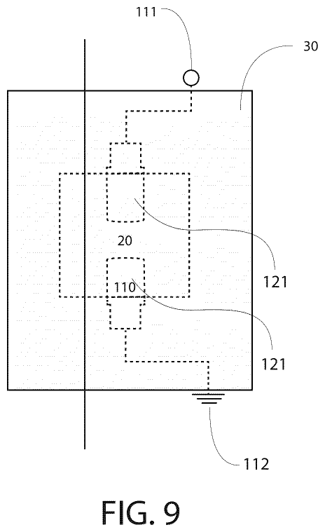

FIG. 9 depicts a cross-sectional orthogonal view of the spark gap structure 100 after encapsulation. The figure shows the semiconductor plastic 30 covering the internal components of the spark gap structure 100. A saw line 900 shows a potential cut line to saw through the semiconductor plastic 30 and expose the sacrificial layer. In some implementations, the sawing line 900 may be indicated on the semiconductor plastic 30. The sawing line 900 may represent where the semiconductor plastic 30 will be cut or ground to expose internal components.

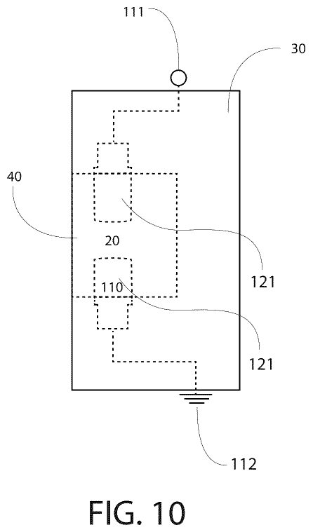

FIG. 10 illustrates the result of sawing along the sawing line 900. In this figure, the sacrificial layer 40 is exposed at one end of the structure. The exposure of the sacrificial layer 40 may allow for subsequent removal to form the spark gap between the inner electrode portions 121.

In some cases, sawing the semiconductor plastic 30 along the sawing line 900 may expose the sacrificial layer 40 for etching. This exposure may create access for the etching process that will remove the sacrificial layer 40 and form the final spark gap.

The semiconductor plastic 30 may continue to provide structural support and electrical isolation for the components while maintaining precise spacing between the electrode portions. The I/O connection 111 and the ground connection 112 may extend through the semiconductor plastic 30, providing electrical connectivity to external circuitry.

In some implementations, sawing the semiconductor plastic 30 to expose the sacrificial layer 40 may occur prior to removing the sacrificial layer 40. This sequence of steps may ensure that the sacrificial layer 40 is accessible for the subsequent etching process while maintaining the structural integrity of the remaining components.

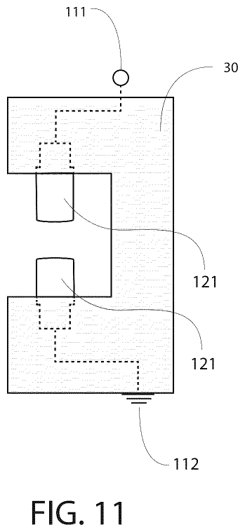

FIG. 11 illustrates a cross-sectional view of the spark gap structure 100 after the removal of the sacrificial layer 40. The removal of the sacrificial layer 40 may form a spark gap between the first electrode 110 and the second electrode 110. In some cases, the sacrificial layer 40 may be removed by etching with an acid. The etching process may selectively remove the sacrificial layer 40 while leaving the surrounding electrode portions intact thanks to their protective plating, without affecting the semiconductor plastic 30 either.

The resulting structure shown in FIG. 11 may include two inner electrode portions 121 positioned opposite each other with a defined gap between them. This gap may serve as the spark gap region. The inner electrode portions 121 may be connected to an input/output connection (I/O) 111 and a ground connection 112 respectively.

In some cases, the semiconductor plastic 30 may encapsulate the electrode portions while maintaining the gap between them. The semiconductor plastic 30 may provide structural support and electrical isolation for the components of the spark gap structure 100. The I/O 111 and ground 112 connections may extend through the semiconductor plastic 30, providing electrical connectivity to external circuitry.

The removal of the sacrificial layer 40 may result in a precisely controlled gap between the inner electrode portions 121. This precise control may allow for tailored spark gap characteristics within the semiconductor plastic 30. The dimensions of the spark gap may be determined by the dimensions of the removed sacrificial layer 40.

In some implementations, the etching process used to remove the sacrificial layer 40 may be selective, meaning the acid used may react with the sacrificial layer 40 material but not with the electrode 110 material or the semiconductor plastic 30. This selectivity may help maintain the integrity of the remaining components of the spark gap structure 100 during the etching process.

The resulting spark gap structure 100 may provide a controlled space for electrical discharge to occur between the I/O connection 111 and the ground connection 112. The precise dimensions of the spark gap, as defined by the removed sacrificial layer 40, may allow for specific voltage breakdown characteristics in the final device.

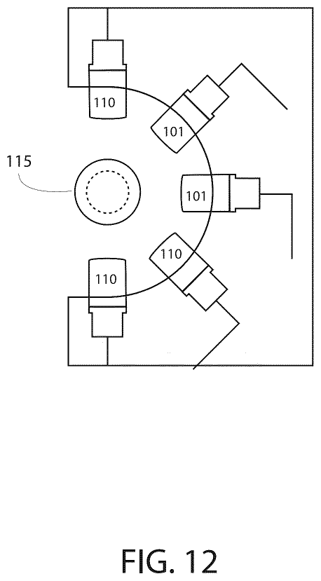

In some cases, the spark gap structure 100 may include multiple electrodes 110 arranged around a circular electrode 1201, as illustrated in FIG. 12. This configuration may provide an alternative arrangement for creating multiple spark gaps within a single device.

FIG. 12 shows a top-down view of a spark gap arrangement where a circular electrode 1201 is positioned centrally with multiple electrodes 110 arranged around the perimeter of the circular electrode 1201. The electrodes 110 may be positioned at regular intervals relative to the circular electrode 1201, creating uniform gaps between each electrode 110 and the circular electrode 1201.

In some implementations, the entire structure may be embedded within the semiconductor plastic 30, which may provide electrical isolation between the components. The arrangement may allow for multiple spark gaps to be formed between the circular electrode 1201 and each surrounding electrode 110, potentially enabling protection across multiple connection points in a compact configuration.

The circular electrode 1201 may serve as either a ground connection or an input/output connection, depending on the specific circuit requirements. In some cases, the surrounding electrodes 110 may be connected to various input/output points of a semiconductor device.

The gaps between the circular electrode 1201 and the surrounding electrodes 110 may be precisely controlled, similar to the electrode gap 20 in the previously described linear arrangements. These gaps may be formed by removing a sacrificial layer 40 that was previously deposited between the circular electrode 1201 and the surrounding electrodes 110.

This circular arrangement may offer advantages in terms of space efficiency and symmetrical protection for multiple connection points. In some cases, this configuration may be particularly useful for devices with numerous input/output connections that require individual spark gap protection.

The spark gap structure 100 may be manufactured using an alternative process that involves the formation of copper pillars. This process may begin with steps similar to those described earlier, including the formation of electrodes 110 on a substrate and the deposition of a protective plating layer on the electrodes 110.

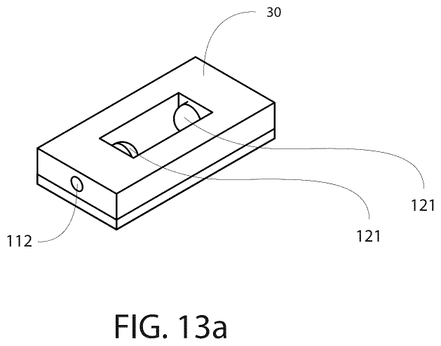

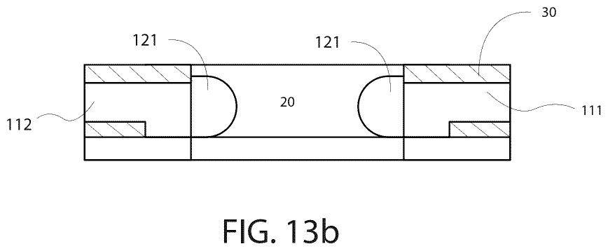

FIG. 13a and FIG. 13b illustrate early stages of this alternative manufacturing process. In FIG. 13a, a semiconductor plastic 30 may be formed around an inner electrode portion 121. A ground connection 112 may extend through the semiconductor plastic 30, providing electrical connectivity.

FIG. 13b shows a cross-sectional view of the structure, revealing two inner electrode portions 121 positioned opposite each other with an electrode gap 20 between them. The inner electrode portions 121 may be partially embedded within the semiconductor plastic 30. An I/O connection 111 may extend from one electrode 110 while a ground connection 112 may extend from the opposite electrode 110 through the semiconductor plastic 30.

In some cases, a sacrificial layer 40 may be deposited between the first electrode 110 and the second electrode 110. The sacrificial layer 40 may occupy the electrode gap 20 between the inner electrode portions 121.

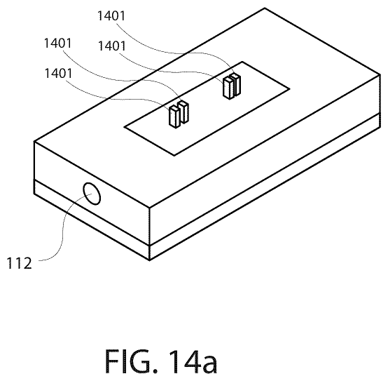

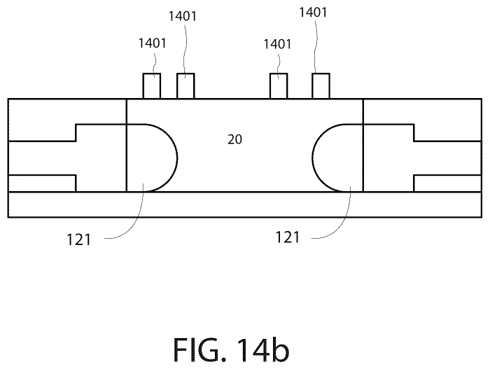

FIG. 14a and FIG. 14b illustrate the next stages of the manufacturing process, which involve the formation of copper pillars 1401. In FIG. 14a, a top-down view of the structure shows copper pillars 1401 positioned around the perimeter of the structure. The copper pillars 1401 may be arranged in a pattern that allows them to serve as access points for subsequent etching processes.

FIG. 14b provides a cross-sectional view of the structure, revealing more details about the arrangement of the copper pillars 1401. The copper pillars 1401 may extend upward from the sacrificial layer 40 through the semiconductor plastic 30. In some cases, the copper pillars 1401 may be arranged in a row along the top of the sacrificial layer 40.

The formation of the copper pillars 1401 may involve depositing additional copper material on top of the sacrificial layer 40. In some cases, this deposition may be performed using electroplating techniques similar to those used for forming the electrodes 110 or the sacrificial layer 40 itself.

After the formation of the copper pillars 1401, the entire structure, including the first electrode 110, the second electrode 110, the sacrificial layer 40, and the copper pillars 1401, may be encapsulated with the semiconductor plastic 30. This encapsulation process may involve applying the semiconductor plastic 30 over the entire structure, ensuring that all components are fully embedded.

In some implementations, the semiconductor plastic 30 may be ground down or otherwise processed to expose the tops of the copper pillars 1401. This exposure may create access points for subsequent etching processes that will remove the sacrificial layer 40 and form the final spark gap.

The copper pillars 1401 may serve as pathways for etchant to reach and remove the sacrificial layer 40 in later stages of the manufacturing process. This approach may allow for the creation of a fully embedded spark gap structure 100 within the semiconductor plastic 30.

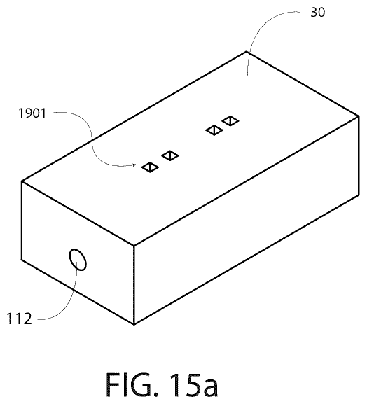

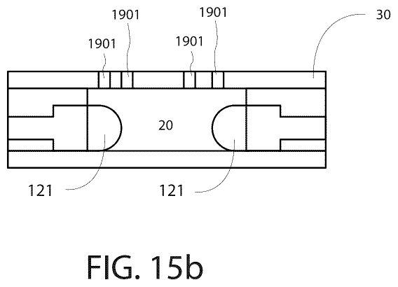

The manufacturing process for the spark gap structure 100 may continue with the etching of the sacrificial layer 40 through the copper pillars 1401. FIG. 15a illustrates an orthogonal view of the spark gap structure 100 after the etching process. The figure shows a block of semiconductor plastic 30 with multiple etchant holes 1501 formed through the structure. In some cases, a ground connection 112 may be visible at one end of the semiconductor plastic 30.

The etchant holes 1501 may be arranged in a pattern that extends through the semiconductor plastic 30, providing pathways for etchant material to reach internal portions of the structure. In some implementations, the etchant holes 1501 may be uniformly sized and spaced within the semiconductor plastic 30.

FIG. 15b provides a cross-sectional orthogonal view of the spark gap structure 100 after the etching process. The figure shows two inner electrode portions 121 positioned opposite each other with an electrode gap 20 between them. The electrode gap 20 may represent the space where the sacrificial layer 40 was previously removed through the etchant holes 1501.

In some cases, the inner electrode portions 121 may be partially embedded within the semiconductor plastic 30, with their facing surfaces exposed to the electrode gap 20. The etchant holes 1501 may extend vertically through the semiconductor plastic 30, providing access channels that were used to remove the sacrificial layer 40 and create the electrode gap 20.

The etching process may involve introducing an etchant material through the etchant holes 1501. This etchant may selectively remove the sacrificial layer 40 while leaving the surrounding electrode portions and semiconductor plastic 30 intact. The selective nature of the etching process may be due to the protective plating layer on the electrodes 110 and the resistance of the semiconductor plastic 30 to the etchant.

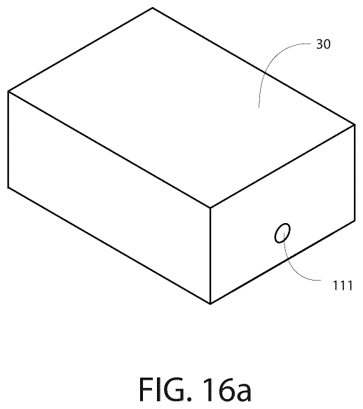

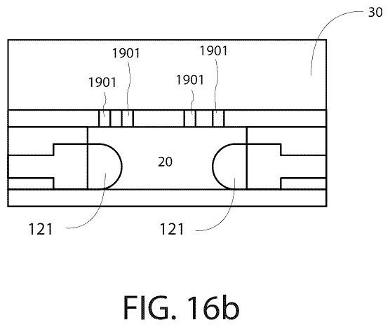

After the etching process, the spark gap structure 100 may be sealed to complete the manufacturing process. FIG. 16a illustrates an orthogonal view of the spark gap structure 100 after sealing. The figure shows a sealing layer 31 that has been placed over the spark gap assembly, forming a block of semiconductor material. In some implementations, a ground connection 112 may extend through the structure.

The sealing layer 31 may provide complete encapsulation of the internal spark gap components, creating a fully embedded spark gap structure 100. In some cases, the sealing layer 31 may form a smooth, continuous surface over the previously formed etchant holes 1501 and gaps, while maintaining electrical connectivity through the ground connection 112.

FIG. 16b provides a cross-sectional view of the sealed spark gap structure 100. The figure shows two inner electrode portions 121 positioned opposite each other with an electrode gap 20 between them. The inner electrode portions 121 may be embedded within the semiconductor plastic 30. In some implementations, four etchant holes 1501 may be visible, positioned above the electrode gap 20.

The sealing process may involve applying an additional layer of semiconductor plastic over the etchant holes 1501. This additional layer may fill and seal the voids left by the etching out of the copper pillars 1401. In some cases, the etchant holes 1501 may be designed to be small enough to prevent the sealing plastic from passing through and filling the electrode gap 20.

The resulting structure may be a fully embedded spark gap, with the electrode gap 20 creating a defined space between the inner electrode portions 121 where electrical discharge can occur. The semiconductor plastic 30 and sealing layer 31 may provide structural support and electrical isolation for the components while maintaining the controlled spark gap spacing defined by the electrode gap 20.

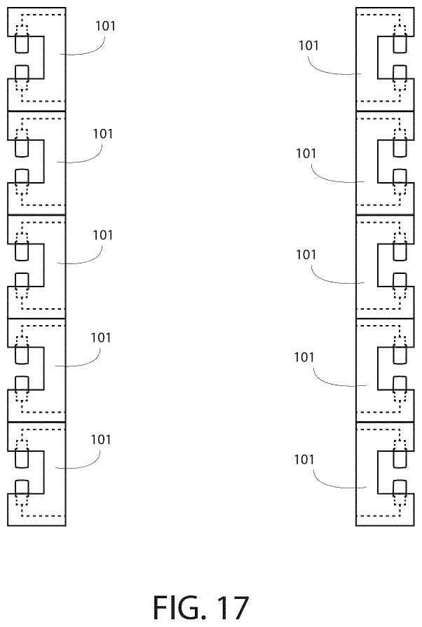

The spark gap structure 100 may be arranged in various configurations to provide protection for multiple connection points within a single device. FIG. 17 illustrates an orthogonal view of a layered spark gap structure showing multiple arraigned spark gaps 101 arranged in two parallel columns. In some cases, the arraigned spark gaps 101 may be positioned to provide protection for each input/output connection of a chip.

The structure shown in FIG. 17 may include multiple sacrificial layers 40 positioned between electrode pairs. The sacrificial layers 40 may be arranged in a repeating pattern along each column, creating a series of spark gap locations. This arrangement may demonstrate how multiple spark gaps may be integrated into a single device structure to provide protection across multiple connection points.

In some implementations, the sacrificial layers 40 may be positioned to define the eventual spark gap dimensions once the sacrificial layers 40 are removed through subsequent processing steps. The precise positioning of the sacrificial layers 40 may allow for controlled and uniform spark gap characteristics across multiple connection points within the device.

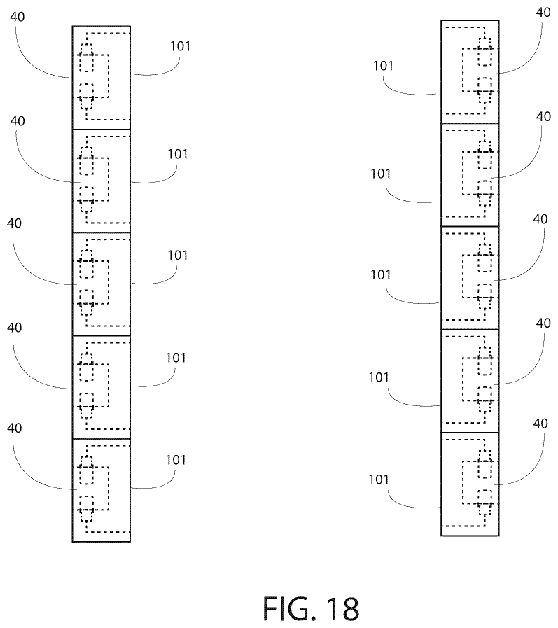

FIG. 18 illustrates a top-down orthogonal view showing a series of arraigned spark gaps 101 arranged in two parallel columns. The arraigned spark gaps 101 may be positioned in a symmetrical pattern, with five spark gaps on each side. This arrangement may demonstrate how multiple spark gaps may be integrated into a single device to provide protection for multiple connection points.

In some cases, the arrangement shown in FIG. 18 may allow for efficient use of space within the semiconductor device while providing comprehensive electrostatic discharge protection. The symmetrical layout of the arraigned spark gaps 101 may contribute to uniform protection characteristics across different connection points as the spark gaps may be formed at the same time.

The multiple spark gap arrangement may be particularly useful for devices with numerous input/output connections that require individual spark gap protection. In some implementations, each arraigned spark gap 101 may be associated with a specific input/output connection, providing tailored protection for each connection point.

The manufacturing process for these multiple spark gap arrangements may involve steps similar to those described for individual spark gaps. In some cases, the process may include forming multiple electrodes 110 on a substrate, depositing sacrificial layers 40 between electrode pairs, and encapsulating the structure with semiconductor plastic 30.

The removal of the sacrificial layers 40 to form the arraigned spark gaps 101 may be performed simultaneously for all spark gaps within the device. This simultaneous removal process may contribute to manufacturing efficiency and consistency in spark gap characteristics across the device.

In some implementations, the multiple spark gap arrangement may be fully embedded within the semiconductor plastic 30, similar to the fully embedded individual spark gap structures described earlier. This embedding may provide protection for the spark gap components while maintaining precise control over the spark gap dimensions.

The arrangement of multiple arraigned spark gaps 101 within a single device may offer advantages in terms of space efficiency, manufacturing simplicity, and comprehensive protection for multi-pin semiconductor chips. By integrating multiple spark gaps directly into the semiconductor packaging, this approach may enable more compact and cost-effective electrostatic discharge protection compared to traditional approaches using separate discrete components for each connection point.

The etched spark gap integrated in semiconductor packaging may provide several advantages and benefits through the interaction of its components. The structure may allow for precise control of spark gap dimensions while being integrated directly into semiconductor packaging, potentially offering improved size efficiency and cost-effectiveness compared to traditional discrete spark gap components.

In some cases, the manufacturing process may involve depositing a protective plating layer on the electrodes. This protective plating layer may comprise multiple materials, each serving specific functions. A nickel layer may be deposited on the electrodes first. Nickel may provide greater mechanical hardness than copper, potentially enhancing the durability of the electrodes.

A palladium layer may then be deposited on the nickel layer. The palladium layer may serve as an intermediate layer, potentially improving adhesion between the nickel and subsequent layers. Following the palladium layer, a gold layer may be deposited. Gold may act as an etch-resistant material, protecting the underlying electrode and plating layers during the etching process used to remove the sacrificial layer.

The use of these multiple plating layers may contribute to the overall functionality and reliability of the spark gap structure. The etch-resistant gold layer may allow for selective removal of the sacrificial layer without damaging the electrodes, while the harder nickel layer may provide mechanical strength to withstand repeated spark events.

In some implementations, the spark gap structure may include an input/output connection electrically coupled to one electrode and a ground connection electrically coupled to the opposite electrode. This configuration may allow the spark gap to provide electrostatic discharge protection between an input/output line and ground.

The integration of the spark gap directly into the semiconductor packaging may offer several potential benefits. The etched nature of the spark gap may allow for precise control over the gap dimensions, potentially enabling tailored protection characteristics. The embedded spark gap structure enables reduced device footprint and lower manufacturing costs compared to discrete spark gap components for chip designers.

Additionally, the manufacturing process may allow for the creation of multiple spark gaps within a single device, potentially providing comprehensive protection for multi-pin semiconductor chips. This approach may offer advantages in terms of space efficiency and manufacturing simplicity compared to using separate discrete components for each connection point.

The combination of precise dimensional control, protective plating layers, and integration within semiconductor packaging may result in a spark gap structure that offers reliable electrostatic discharge protection while potentially reducing overall device size and manufacturing complexity.

A number of implementations have been described. Nevertheless, it will be understood that various modifications may be made without departing from the spirit and scope of the disclosure. Accordingly, other implementations are within the scope of the following claims.

1. A semiconductor device, comprising:
a first electrode and a second electrode positioned opposite each other with a gap between them;
a semiconductor plastic encapsulating the first electrode and the second electrode;
a protective plating layer on the first electrode and the second electrode; and
a sacrificial layer positioned within the gap, wherein the sacrificial layer is removable to form a spark gap between the first electrode and the second electrode.

2. The semiconductor device of claim 1, wherein the sacrificial layer is an etchable metal.

3. The semiconductor device of claim 2, wherein the protective plating layer comprises at least one etch resistant material.

4. The semiconductor device of claim 3, wherein at least one of the etch resistant materials is a gold metal.

5. The semiconductor device of claim 3, wherein the protective plating layer comprises at least one material with a greater mechanical hardness than copper.

6. The semiconductor device of claim 5, wherein at least one of the materials with a greater mechanical hardness than copper is a nickel metal.

7. The semiconductor device of claim 1, wherein the sacrificial layer comprises a copper metal.

8. The semiconductor device of claim 1, wherein the sacrificial layer is removed.

9. A method of manufacturing a semiconductor device with an integrated spark gap, comprising:
forming a first electrode and a second electrode on a substrate;
depositing a sacrificial layer between the first electrode and the second electrode;
depositing a protective plating layer on the first electrode and the second electrode;
encapsulating the first electrode, the second electrode, and the sacrificial layer with a semiconductor plastic; and
removing the sacrificial layer to form a spark gap between the first electrode and the second electrode.

10. The method of claim 9, wherein the protective plating layer comprises at least one etch resistant material.

11. The method of claim 10, wherein the etch resistant material is a gold metal.

12. The method of claim 9, wherein removing the sacrificial layer comprises etching the sacrificial layer with an acid.

13. The method of claim 9, further comprising:
forming an input/output connection electrically coupled to the first electrode; and
forming a ground connection electrically coupled to the second electrode.

14. The method of claim 9, further comprising sawing the semiconductor plastic to expose the sacrificial layer prior to removing the sacrificial layer.

15. The method of claim 9, wherein depositing the protective plating layer comprises:
depositing a nickel layer on the first electrode and the second electrode;
depositing a palladium layer on the nickel layer; and
depositing a gold layer on the palladium layer.

16. A method of manufacturing a semiconductor device with an embedded spark gap, comprising:
forming a first electrode and a second electrode on a substrate;
depositing a protective plating layer on the first electrode and the second electrode prior to depositing the sacrificial layer;
depositing a sacrificial layer between the first electrode and the second electrode;
forming copper pillars on the sacrificial layer;
encapsulating the first electrode, the second electrode, the sacrificial layer, and the copper pillars with a semiconductor plastic;
exposing the copper pillars; and
etching out the sacrificial layer through the exposed copper pillars to form a spark gap between the first electrode and the second electrode.

17. The method of claim 16, wherein the protective plating layer comprises at least one etch resistant material.

18. The method of claim 16, wherein the etch resistant material is a gold metal.

19. The method of claim 16, wherein depositing the protective plating layer comprises:
depositing a nickel layer on the first electrode and the second electrode;
depositing a palladium layer on the nickel layer; and
depositing a gold layer on the palladium layer.

20. The method of claim 16, further comprising sealing at least one void, left by the etching out of the copper pillars, with an additional layer of semiconductor plastic.
